(19) United States
(12) Patent Application Publication
(10) Pub. No.: US 2025/0167742 A1
(43) Pub. Date: May 22, 2025

(54) RADIO FREQUENCY POWER AMPLIFIER

(71) Applicant: RichWave Technology Corp., Taipei (TW)

(72) Inventor: Yu-Chun Donald Lie, Taipei (TW)

(73) Assignee: RichWave Technology Corp., Taipei (TW)

(21) Appl. No.: 18/515,284

(22) Filed: Nov. 21, 2023

(51) Int. Cl. H03F 3/24; H03F 1/56

(52) U.S. Cl. CPC H03F 3/245; H03F 1/565; H03F 2200/222; H03F 2200/387; H03F 2200/451

(57) ABSTRACT

A radio frequency power amplifier includes an input terminal, at least two amplifier paths, an asymmetric power combination circuit, and an output terminal. The input terminal receives a radio frequency signal. Each of the amplifier paths is coupled to the input terminal. Each of the amplifier paths amplifies the radio frequency signal to generate a corresponding amplified radio frequency signal. The asymmetric power combination circuit is coupled to the amplifier paths and combines the amplified radio frequency signals generated by the amplifier paths to generate a combined radio frequency signal. The output terminal outputs the combined radio frequency signal. Each of the amplifier paths generates the corresponding amplified radio frequency signal simultaneously, and a reverse isolation of each of the amplifier paths is better than about 35 dB.

### BACKGROUND

### Technical Field

The disclosure relates to a circuit design of wireless communication technology, and particularly, to a radio frequency power amplifier.

### Related Art

In wireless communication technology, it is desired to design a radio frequency amplifier using an integrated circuit or chip of limited volume while enabling this radio frequency amplifier to generate precise or higher radio frequency output power. In this manner, the signal transmission range of wireless communication technology can be further expanded. Conventionally, multiple radio frequency amplifier stage circuits of the same structure are generally connected in parallel with each other to increase the output power of the signal, but it is difficult for such a circuit structure to increase the bandwidth and the power-added efficiency (PAE) of the final output signal, and such a circuit design is also accompanied with unavoidable parasitic capacitance effects and signal losses. With the growing demand for higher communication data transmission rates and low energy consumption and the shift from 3G communication protocol to 5G communication protocol, both the signal bandwidth (e.g., increased from 5 MHz to 400 MHZ) and operating frequency (e.g., increased from 1.9 GHz to 39 GHz) of the radio frequency amplifier are constantly increasing. In other words, broadband, high-power, and high-efficiency radio frequency amplifiers are highly valued in wireless communication technology, which makes the circuit design of radio frequency amplifiers challenging.

### SUMMARY

A radio frequency power amplifier according to an embodiment of the disclosure includes an input terminal, at least two different amplifier paths, an asymmetric power combination circuit, and an output terminal. The input terminal receives a radio frequency signal. Each of the amplifier paths is coupled to the input terminal. Each of the amplifier paths amplifies the radio frequency signal to generate a corresponding amplified radio frequency signal. The asymmetric power combination circuit is coupled to the amplifier paths. The asymmetric power combination circuit combines the amplified radio frequency signals generated by the amplifier paths to generate a combined radio frequency signal. The output terminal outputs the combined radio frequency signal. Each of the amplifier paths generates the corresponding amplified radio frequency signal simultaneously, and a reverse isolation of each of the amplifier paths is better than about 35 dB.

### BRIEF DESCRIPTION OF DRAWINGS

FIG. 1 illustrates a block diagram of a radio frequency power amplifier according to a first embodiment of the disclosure.

FIG. 2 illustrates a block diagram of a radio frequency power amplifier according to a second embodiment of the disclosure.

FIG. 3 illustrates a block diagram of a radio frequency power amplifier according to a third embodiment of the disclosure.

FIG. 4 illustrates a block diagram of a radio frequency power amplifier according to a fourth embodiment of the disclosure.

FIG. 5 illustrates a block diagram of a radio frequency power amplifier according to a fifth embodiment of the disclosure.

FIG. 6 illustrates a circuit diagram of a radio frequency power amplifier according to a sixth embodiment of the disclosure.

FIG. 7 to FIG. 12 are schematic circuit diagrams of each amplifier stage circuit located in an amplifier path according to embodiments of the disclosure.

FIG. 13 illustrates a schematic circuit diagram of a radio frequency power amplifier according to a seventh embodiment of the disclosure.

FIG. 14 illustrates a schematic circuit diagram of a radio frequency power amplifier according to an eighth embodiment of the disclosure.

FIG. 15 illustrates a schematic circuit diagram of a radio frequency power amplifier according to a ninth embodiment of the disclosure.

### DESCRIPTION OF EMBODIMENTS

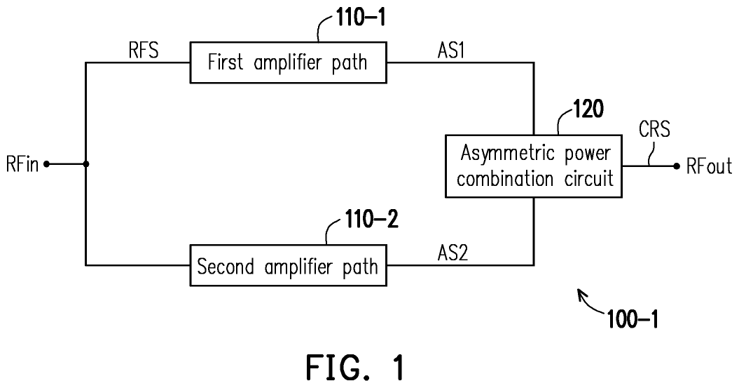

FIG. 1 illustrates a block diagram of a radio frequency power amplifier 100-1 according to a first embodiment of the disclosure. The radio frequency power amplifier 100-1 includes an input terminal RFin, at least two different amplifier paths, an asymmetric power combination circuit 120, and an output terminal RFout. The input terminal RFin receives a radio frequency signal. The radio frequency power amplifier 100-1 processes and amplifies a radio frequency signal RFS to output, via the output terminal RFout, to a load (e.g., a back-end load circuit, or an antenna) coupled to the output terminal RFout.

The radio frequency power amplifier of the embodiments of the disclosure includes at least two different amplifier paths. In FIG. 1, the radio frequency power amplifier 100-1 includes two different amplifier paths (i.e., a first amplifier path 110-1 and a second amplifier path 110-2). Each of the amplifier paths 110-1 and 110-2 is coupled to the input terminal RFin. The amplifier paths 110-1 and 110-2 are configured to amplify the radio frequency signal RFS to generate corresponding amplified radio frequency signals AS1 and AS2, respectively. The circuit structures/parameters of the amplifier paths 110-1 and 110-2 in this embodiment are not the same as each other (e.g., different transistor sizes, bias voltages, phases, signal gains, etc.), so the amplifier paths 110-1 and 110-2 form an asymmetric circuit structure. The asymmetric power combination circuit 120 is coupled to the amplifier paths 110-1 and 110-2. The asymmetric power combination circuit 120 is configured to combine the amplified radio frequency signals AS1 and AS2 generated by the amplifier paths 110-1 and 110-2 to create a combined radio frequency signal CRS. The output terminal RFout is configured to output the combined radio frequency signal CRS. The amplifier paths 110-1 and 110-2 simultaneously generates the corresponding amplified radio frequency signals AS1 and AS2. Since the output matching from the asymmetric power combination circuit 120 interacts with the circuits in the amplifier paths 110-1 and 110-2, the combined output power Pout and power-added efficiency (PAE) of the combined radio frequency power amplifier may be reduced. In this embodiment, a reverse isolation of each of the amplifier paths 110-1 and 110-2 is designed to be better than about 35 dB to increase the output power Pout and the PAE of the radio frequency power amplifier 100-1. For example, the reverse isolation of each of the amplifier paths 110-1 and 110-2 is designed to be better than 35 to 40 dB, depending on the frequency of operation, etc. The “reverse isolation” described in this embodiment refers to an amplifier reverse transmission response measured from the output terminal to the input terminal of the amplifier paths 110-1 or 110-2.

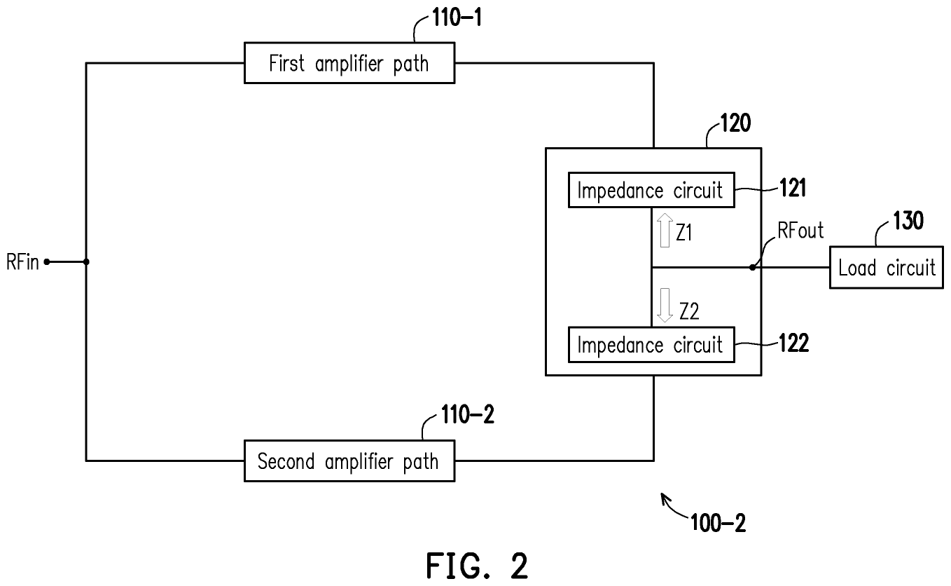

FIG. 2 illustrates a block diagram of a radio frequency power amplifier 100-2 according to a second embodiment of the disclosure. FIG. 2 mainly presents a detailed block structure of a load circuit 130 and the asymmetric power combination circuit 120 in the radio frequency power amplifier 100-2. The radio frequency power amplifier 100-2 in FIG. 2 further includes a load circuit 130 coupled to the output terminal RFout. The load circuit 130 may be a back-end circuit structure, an antenna, or a combination of the two.

The asymmetric power combination circuit 120 of the radio frequency power amplifier 100-2 in FIG. 2 includes impedance circuits 121 and 122. The impedance circuit 121 is coupled between the output terminal RFout and the amplifier path 110-1. The impedance circuit 122 is coupled between the output terminal RFout and the amplifier path 110-2. In this embodiment, the circuit structures/parameters of the impedance circuits 121 and 122 are not exactly the same as each other, so the impedance circuits 121 and 122 form an asymmetric circuit structure. Taking the output terminal RFout as a reference, the impedance circuit 121 has an impedance Z1 and the impedance circuit 122 has an impedance Z2. In other words, when viewing from the output terminal RFout toward the impedance circuits 121 and 122, the impedance circuits 121 and 122 respectively have the impedances Z1 and Z2.

This embodiment is designed such that the impedances Z1 and Z2 are substantially complex conjugate matched. In this embodiment, the impedance circuits 121 and 122 are designed such that an impedance difference between the impedances Z1 and Z2 is within ±25%. Moreover, an equivalent impedance formed by the impedances Z1 and Z2 is substantially equal to the impedance of the load circuit 130. Accordingly, the signal bandwidth of the radio frequency power amplifier is increased. For example, by design, the impedance of the load circuit 130 may be 50 ohms (Ω), and then the impedances Z1 and Z2 are designed toward 100 ohms. Since the impedances Z1 and Z2 are connected in parallel with each other, the impedance value formed after connecting the impedances Z1 and Z2 in parallel is about 50 ohms.

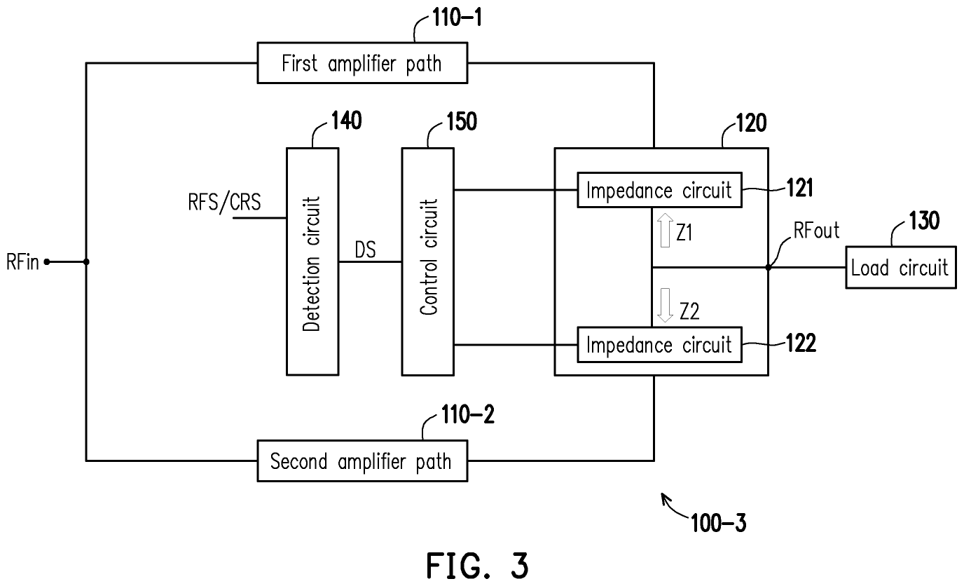

FIG. 3 illustrates a block diagram of a radio frequency power amplifier 100-3 according to a third embodiment of the disclosure. In this embodiment, the impedance Z1 corresponding to the impedance circuit 121 and the impedance Z2 corresponding to the impedance circuit 122 are variable. In this embodiment, circuit elements (e.g., variable capacitors, variable resistors, variable inductors, etc.) capable of being controlled to adjust their own values may be provided in the internal structures of the impedance circuits 121 and 122, and these circuit elements may be controlled by a control circuit 150.

The radio frequency power amplifier 100-3 in FIG. 3 further includes a detection circuit 140 and a control circuit 150. The detection circuit 140 is configured to detect an electrical property of the radio frequency signal RFS or the combined radio frequency signal CRS to generate a detection signal DS. The electrical property may be a signal frequency, a signal power, etc. of the signal. The control circuit 150 is coupled to the detection circuit 140. According to the detection signal DS, the control circuit 150 controls at least a part of the circuit elements in the impedance circuits 121 and 122 to adjust the impedance Z1 and the impedance Z2 to thus adaptively adjust the properties of the radio frequency power amplifier. The properties of the radio frequency power amplifier include, for example, a gain, a 1 dB compression point (OP1 dB), a maximum power-added efficiency (Max. PAE), and/or a saturated output power (Pout, SAT).

For example, the detection circuit 140 is configured to detect a signal frequency of the radio frequency signal RFS or the combined radio frequency signal CRS, and generate a detection signal DS associated with the signal frequency according to a look-up table. The control circuit 150 controls the variable circuit elements in the impedance circuits 121 and 122 according to the detection signal DS to adjust the impedance Z1 and the impedance Z2, such that the properties of the power amplifier can still remain within a reasonable range when the signal frequency changes to further increase the signal bandwidth of the radio frequency power amplifier. The detection circuit 140 and the control circuit 150 in FIG. 3 may be applied to multiple embodiments of the disclosure. However, for convenience of illustrating other contents, the detection circuit 140 and the control circuit 150 are not additionally illustrated in the corresponding figures of other embodiments.

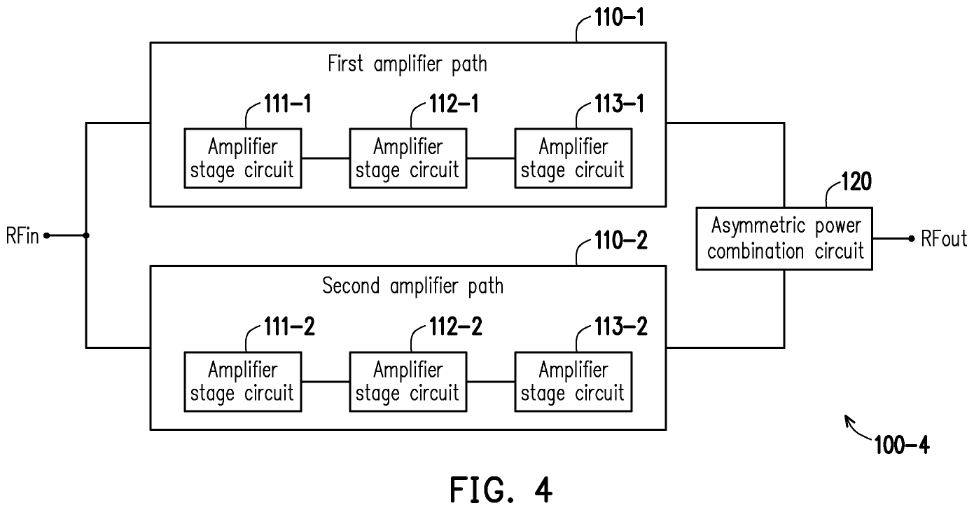

FIG. 4 illustrates a block diagram of a radio frequency power amplifier 100-4 according to a fourth embodiment of the disclosure. Each of the amplifier paths 110-1 and 110-2 of the radio frequency power amplifier 100-4 in FIG. 4 may include a plurality of cascaded amplifier stage circuits. To configure the reverse isolation of each of the amplifier paths 110-1 and 110-2 to be better than about 35 dB (for example, better than 35 to 40 dB, depending on the frequency of operation, etc.), the number of the cascaded amplifier stage circuits in each of the amplifier paths 110-1 and 110-2 may be designed to be greater than or equal to three. For example, the amplifier path 110-1 includes three amplifier stage circuits 111-1 to 113-1, and the amplifier path 110-2 includes three amplifier stage circuits 111-2 to 113-2. Compared to an embodiment in which the amplifier paths 110-1 and 110-2 only include two amplifier stage circuits, in the fourth embodiment of the disclosure, since the order of amplifier stage circuits is higher, there are also more corresponding matching circuits, which is generally considered to be more likely to interact with the output matching from the asymmetric power combination circuit 120 and thus may reduce the output power (Pout) and the PAE of the radio frequency power amplifier 100-1. However, in the fourth embodiment of the disclosure, since the order of amplifier stage circuits is increased, the reverse isolation of the amplifier paths 110-1 and 110-2 is increased, which reduces the interaction between the matching circuits in the amplifier paths 110-1 and 110-2 and the output matching of the asymmetric power combination circuit 120 and thus can actually increase the output power (Pout) and the PAE of the radio frequency power amplifier 100-1.

In detail, when designing the radio frequency power amplifier 100-4 in this embodiment, two amplifier paths 110-1 and 110-2 are connected in parallel with each other, the amplifier paths 110-1 and 110-2 respectively include three amplifier stage circuits 111-1 to 113-1 and 111-2 to 113-2, and the amplifier stage circuits 111-1 to 113-1 and 111-2 to 113-2 in the amplifier paths 110-1 and 110-2 may each have amplifier configurations of different types. The amplifier configurations include, for example, common source amplifiers, common emitter amplifiers, cascode amplifiers, multi-stacked-transistors amplifiers, multiple types of cascade amplifiers and cascode amplifiers, etc.

This embodiment may also be designed such that the amplifier stage circuits (e.g., the amplifier stage circuits 111-1 and 111-2, 112-1 and 112-2, 113-1 and 113-2) of the same order in the amplifier paths 110-1 and 110-2 are of the same configuration (for example, the amplifier stage circuits in the amplifier paths are all common source amplifiers or common emitter amplifiers), and the amplifier stage circuits of the same order in the amplifier paths respectively have different transistor sizes. In this manner, in the radio frequency power amplifier 100-4, the amplifier paths 110-1 and 110-2 may be designed to form an asymmetric circuit structure.

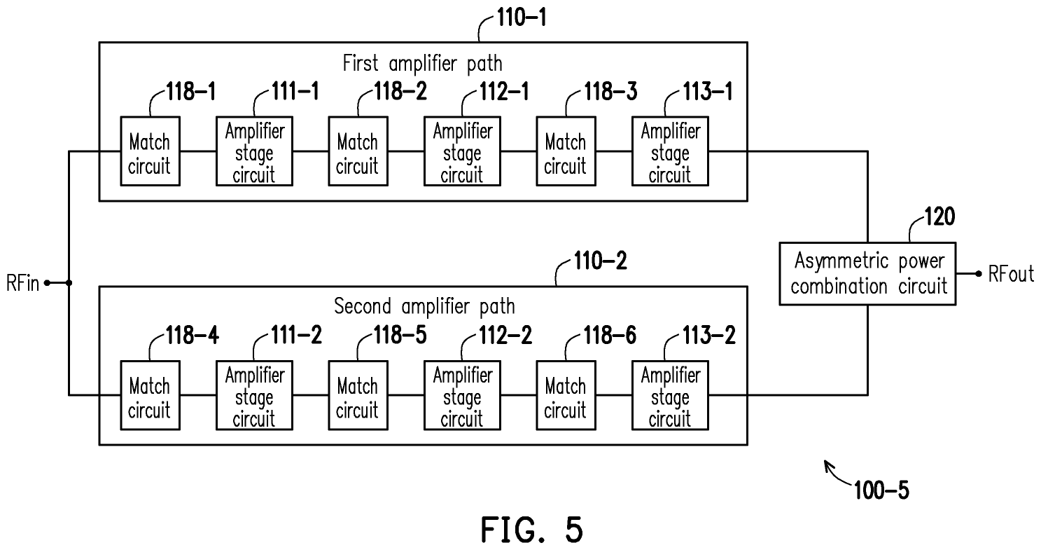

FIG. 5 illustrates a block diagram of a radio frequency power amplifier 100-5 according to a fifth embodiment of the disclosure. The radio frequency power amplifier 100-5 in FIG. 5 further includes at least one impedance matching circuit, e.g., matching circuits 118-1 to 118-6 in FIG. 5. The matching circuits 118-2, 118-3, 118-5, and 118-6 are coupled between the amplifier stage circuits 111-1 to 113-1 and 111-2 to 113-2 cascaded in the amplifier paths 110-1 and 110-2. The matching circuit 118-1 is coupled between the input terminal RFin and the amplifier stage circuit 111-1 coupled to the input terminal RFin in the amplifier path 110-1. The matching circuit 118-4 is coupled between the input terminal RFin and the amplifier stage circuit 111-2 coupled to the input terminal RFin in the amplifier path 110-2. A person implementing this embodiment may design the matching circuits 118-1 to 118-6 to suitably adjust the signal gain, the bandwidth, the output impedance, the power consumption, etc. of the amplifier paths 110-1 and 110-2.

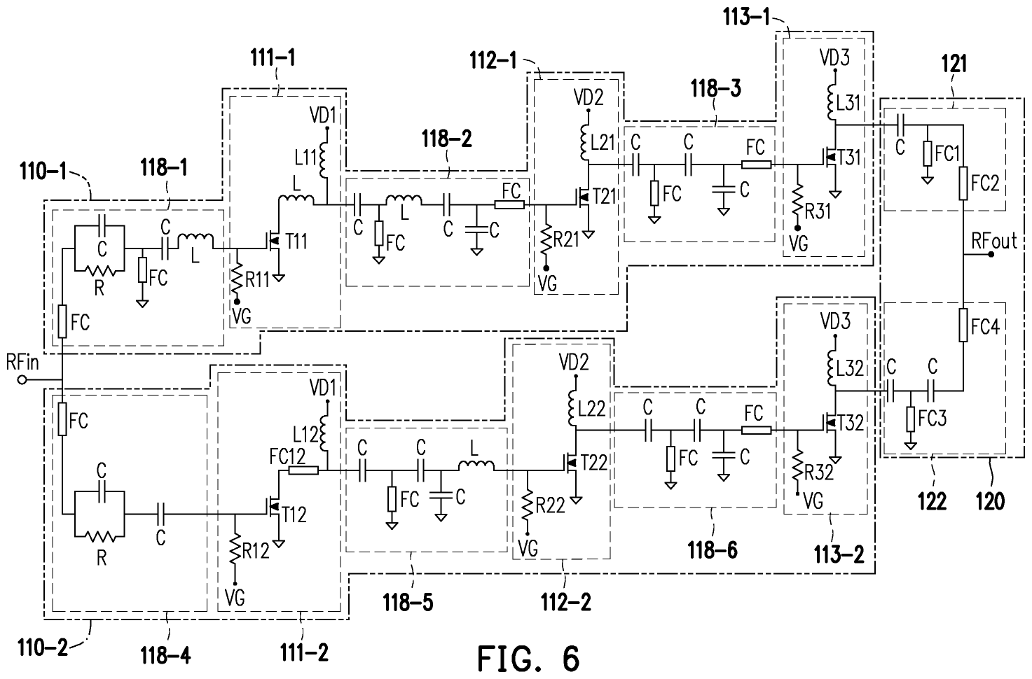

FIG. 6 illustrates a circuit diagram of a radio frequency power amplifier 600 according to a sixth embodiment of the disclosure. The radio frequency power amplifier 600 is a detailed circuit configuration in line with the radio frequency power amplifier 100-5 in FIG. 5. In the sixth embodiment, the amplifier stage circuits 111-1 to 113-1 and 111-2 to 113-2 cascaded in the amplifier paths 110-1 to 110-2 in FIG. 6 are all common source amplifiers (or common emitter amplifiers), but can be cascode amplifiers, which will improve the reverse isolation compared to the common source amplifiers with better reverse isolation properties. Specifically, taking the amplifier stage circuit 111-1 as an example, the amplifier stage circuit 111-1 is configured to receive an operating voltage VD1 and includes a transistor T11, a resistor R11, and an inductor L11 that constitute a common source amplifier. A control terminal of the transistor T11 is configured to input a radio frequency signal, a first terminal (drain terminal) of the transistor T11 is configured to receive the operating voltage VD1 and output an amplified radio frequency signal, and a second terminal (source terminal) of the transistor T11 is configured to receive a reference voltage. The amplifier stage circuit 111-1 further includes other circuit elements (e.g., an inductor L) to adaptively adjust the signal gain, the bandwidth, the output impedance, the power consumption, etc. of the amplifier paths 110-1 and 110-2. Similar to the circuit structure of the amplifier stage circuit 111-1, the amplifier stage circuits 112-1, 113-1, 111-2, 112-2, and 113-2 are respectively configured to receive operating voltages VD2, VD3, VD1, VD2, and VD3 and include transistors T21, T31, T12, T22, and T32, resistors R21, R31, R12, R22, and R32, and inductors L21, L31, L12, L22, and L32 that constitute common source amplifiers. The amplifier stage circuit 112-1 further includes other circuit elements, such as a filter circuit FC12.

In addition, in the amplifier paths 110-1 and 110-2, among the common source amplifiers or common emitter amplifiers of the same order (e.g., the common source amplifiers of amplifier stage circuits 111-1 and 111-2, 112-1 and 112-2, 113-1 and 113-2), the common source amplifiers or common emitter amplifiers of at least one order may have transistor sizes different from each other. The common source amplifiers or common emitter amplifiers of the same order in the amplifier paths 110-1 and 110-2 may also each have different transistor sizes. For example, in this embodiment, the size of the transistor T11 in the common source amplifier of the amplifier stage circuit 111-1 is 2×25 micrometers (μm), and the size of the transistor T12 in the common source amplifier of the amplifier stage circuit 111-2 is 2×15 μm; the size of the transistor T21 is 2×50 μm, and the size of the transistor T22 is 2×25 μm; and the size of the transistor T31 is 4×75 μm, and the size of the transistor T32 is 4×50 μm. Thus, the circuit structures/parameters of the amplifier paths 110-1 and 110-2 are not the same as each other, and the radio frequency power amplifier 600 has an asymmetric circuit structure.

The matching circuits 118-1 to 118-6 may be implemented by a resistor R, a capacitor C, an inductor L, a filter circuit FC, or any combination of the four. Although the resistors, the capacitors, and the inductors are respectively labeled as R, C, and L in the corresponding circuits of the matching circuits 118-1 to 118-6, the values of each resistor R, each capacitor C, and each inductor L are not necessarily the same as each other. Instead, the values of the resistor R, the capacitor C, and the inductor L may be adjusted by a person implementing this embodiment according to the requirements. The filter circuit (e.g., the filter circuits FC and FC12) in the embodiments of the disclosure may be a resistor or a circuit composed of inductor-capacitor (LC) elements or resistor-inductor-capacitor (RLC) elements, and the circuit structure of each filter circuit is not necessarily the same as each other. A person implementing this embodiment may adjust the circuit structure of each filter circuit according to the requirements.

The asymmetric power combination circuit 120 includes impedance circuits 121 and 122. The circuit structures of the impedance circuits 121 and 122 in FIG. 6 are different from each other. The impedance circuit 121 is composed of a capacitor C and two filter circuits FC1 and FC2. The impedance circuit 122 is composed of two capacitors C and two filter circuits FC3 and FC4.

Table 1 presents some simulated properties of the radio frequency power amplifier 600 from 26 to 30 GHz. Since the number of amplifier stage circuits cascaded in each of the amplifier paths 110-1 and 110-2 of the radio frequency power amplifier 600 is designed to be greater than or equal to three, it is possible to configure the reverse isolation of each of the amplifier paths 110-1 and 110-2 to be better than about 35 dB and thus providing better gain, 1 dB compression point (OP1 dB), maximum power-added efficiency (Max. PAE), and saturated output power (Pout, SAT) of the radio frequency power amplifier 600 at multiple frequencies, which also satisfy the requirements for broadband operation.

TABLE 1

| | | | |
|---|---|---|---|
| Frequency (GHz) | 26 | 28 | 30 |
| Gain (dB) | 25.5 | 26.6 | 25.8 |
| OP1dB (dBm) | 17.2 | 12.1 | 13.6 |
| Max. PAE (%) | 28.1 | 16.3 | 27.9 |
| Pout, SAT (dBm) | 21.7 | 19.2 | 21 |

In the sixth embodiment, the amplifier stage circuits 111-1, 112-1, 113-1, 111-2, 112-2, and 113-2 in FIG. 6 are respectively configured to receive the operating voltages VD1, VD2, VD3, VD1, VD2, and VD3. The embodiment corresponding to Table 1 is an example in which VD1, VD2, and VD3 are the same as each other. In other embodiments, VD1, VD2, and VD3 may also be different from each other. For example, VD3 is greater than VD2 and VD1. In other words, the operating voltage VD3 of the last-order amplifier stage circuits 113-1 and 113-2 in the amplifier paths 110-1 and 110-2 may be greater than the operating voltages VD1 and VD2 of the other-order amplifier stage circuits 111-1 to 111-2 and 112-1 to 112-2. Referring to Table 2, Table 2 presents some properties of the radio frequency power amplifier 600 when VD3 is greater than VD2 and VD1, for example, when VD3 is 1 volt greater than VD2 and VD1.

TABLE 2

| | | | |
|---|---|---|---|
| Frequency (GHz) | 25.5 | 28 | 30 |
| Gain (dB) | 28.1 | 26.6 | 31 |
| OP1dB (dBm) | 22.3 | 16.1 | 17.2 |
| Max. PAE (%) | 38.6 | 21.9 | 31 |
| Pout, SAT (dBm) | 22.5 | 19.9 | 21.2 |

Compared to the embodiment corresponding to Table 1 (VD1, VD2, and VD3 are the same as each other), in the embodiment corresponding to Table 2 (VD3 is greater than VD2 and VD1), it is possible to provide better gain, 1 dB compression point (OP1 dB), maximum power-added efficiency (Max. PAE), and saturated output power (Pout, SAT) of the radio frequency power amplifier 600 at multiple frequencies, which thus better satisfies the requirements for broadband operation. Table 3 is shown measurement results of the embodiments corresponding of table 1 and table 2. In table 3, the embodiment corresponding of the table 2 has better properties than the embodiment corresponding of table 1.

TABLE 3

| | |
|---|---|
| Embodiment of | Embodiment of |
| table 2 | table 1 |

| | |
|---|---|
| Frequency (GHz) | 25.5 |

| | | |
|---|---|---|
| Supply Voltage (V) | VD1 = VD2 = 3 V, | VD1 = VD2 = |
| | VD3 = 4 V | VD3 = 4 V |
| Gain (dB) | 28.1 | 26.2 |
| OP1dB (dBm) | 22.3 | 21.1 |
| PAE@ P1dB (%) | 37.5 | 29 |
| Max. PAE (%) | 38.6 | 29.5 |

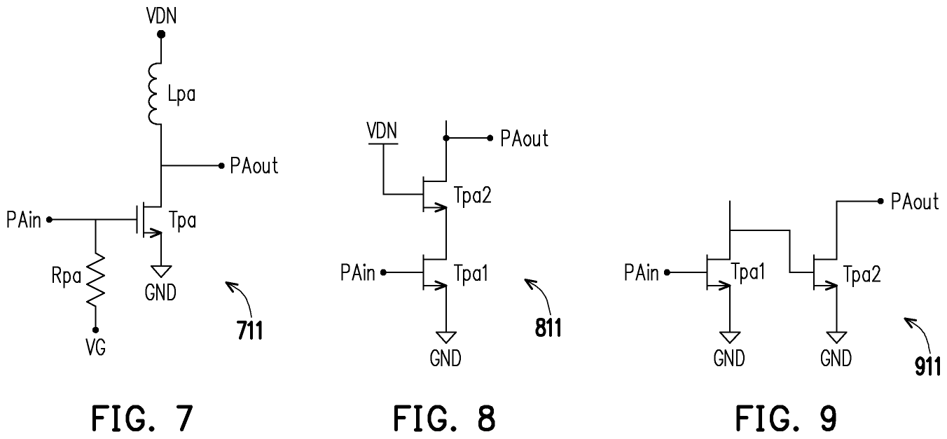

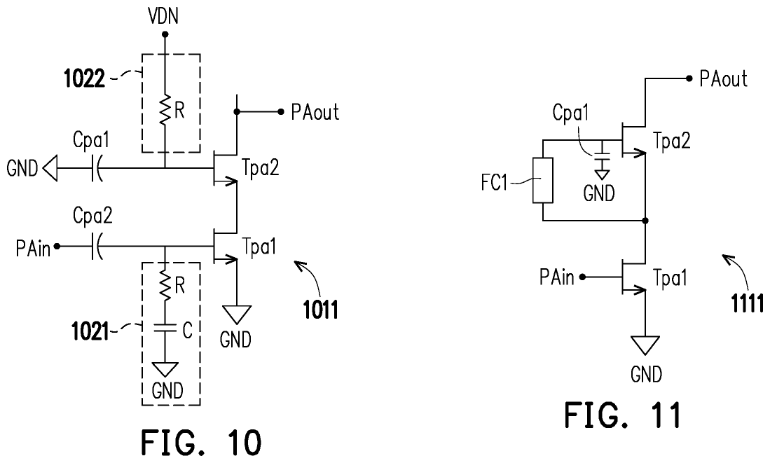

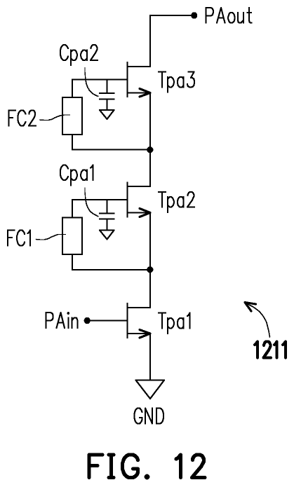

In addition, since the common source amplifier and the common emitter amplifier have better reverse isolation properties, the sixth embodiment is an example in which the amplifier stage circuits are all common source amplifiers to better configure the reverse isolation of each amplifier path to be better than about 35 dB. However, in other embodiments, in addition to implementing the amplifier stage circuits 111-1 to 113-1 and 111-2 to 113-2 in FIG. 6 by common source amplifiers or common emitter amplifiers, the amplifier stage circuits 111-1 to 113-1 and 111-2 to 113-2 in FIG. 6 may also be implemented by cascode amplifiers or cascade amplifiers of different types to also configure the reverse isolation of each amplifier path to be better than about 35 dB. FIG. 7 to FIG. 12 are schematic circuit diagrams of each amplifier stage circuit located in the amplifier path according to embodiments of the disclosure. A person implementing this embodiment may selectively apply the amplifier stage circuits in FIG. 7 to FIG. 12 to each amplifier stage circuit in the radio frequency power amplifier in FIG. 1 to FIG. 6. For example, the amplifier stage circuits in the radio frequency power amplifier 600 in FIG. 6 may all be common source amplifiers (corresponding to FIG. 6 and FIG. 7), common emitter amplifiers, cascode amplifiers (corresponding to FIG. 8), cascade amplifiers (corresponding to FIG. 9), two-stack amplifiers (corresponding to FIG. 10), cascode amplifiers which is a common-source amplifier in cascade with a common-gate amplifier (corresponding to FIG. 11), or multi-stacked-transistors amplifier (e.g., three-stacked-transistors amplifier, etc., corresponding to FIG. 12). In addition, since the last-order amplifier stage circuit among the plurality of cascaded amplifier stage circuits provides a large portion of the reverse isolation properties, as an example, the amplifier stage circuits 113-1 and 113-2 in the amplifier paths 110-1 and 110-2 in FIG. 6 that are coupled to the asymmetric power combination circuit 120 (that is, the last-order amplifier stage circuits among the plurality of cascaded amplifier stage circuits corresponding to different amplifier paths) can be cascode amplifiers, which will improve the reverse isolation compared to the common source amplifiers (or common emitter amplifiers) with better reverse isolation properties. Therefore, in other embodiments, the last-order amplifier stage circuit may also be changed from a common source amplifier (corresponding to FIG. 6 and FIG. 7) to a common emitter amplifier, a cascode amplifier (corresponding to FIG. 8), a cascade amplifier (corresponding to FIG. 9), a two-stack amplifier (corresponding to FIG. 10), a cascode amplifier in according with a common-source amplifier in cascade with a common-gate amplifier (corresponding to FIG. 11), or a multi-stacked-transistors amplifier (e.g., three-stacked-transistors amplifier, etc., corresponding to FIG. 12) to also configure the reverse isolation of each amplifier path to be better than about 35 dB.

Herein, each amplifier stage circuit in FIG. 7 to FIG. 12 will be described in detail. In FIG. 7 to FIG. 12, transistors Tpa, Tpa1, and Tpa2 may be implemented by metal-oxide-semiconductor field-effect transistors (MOSFET), and a first terminal, a second terminal, and a control terminal of the transistors Tpa, Tpa1, and Tpa2 may respectively be a drain terminal, a source terminal, and a gate terminal. In other embodiments in line with the disclosure, the transistors Tpa, Tpa1, and Tpa2 in FIG. 7 to FIG. 12 may also be implemented by bipolar junction transistors (BJT), and the first terminal, the second terminal, and the control terminal of the transistors Tpa1 and Tpa2 may also be a collector terminal, an emitter terminal, and a base terminal, respectively.

Referring to FIG. 7, an amplifier stage circuit 711 in FIG. 7 is a common source amplifier. The amplifier stage circuit 711 includes an input terminal PAin, a transistor Tpa, an inductor Lpa, and an output terminal PAout. A control terminal (gate terminal) of the transistor Tpa is coupled to the input terminal PAin. A second terminal (source terminal) of the transistor Tpa is coupled to a reference voltage terminal GND, and a first terminal (drain terminal) of the transistor Tpa is coupled to the output terminal PAout and one terminal of the inductor Lpa. The other terminal of the inductor Lpa is coupled to an operating voltage terminal VDN. The amplifier stage circuit 711 may optionally include a resistor Rpa, and the resistor Rpa is coupled between the input terminal PAin and an operating voltage terminal VG. The amplifier stage circuit 711 may also be replaced with a common emitter amplifier, and the first terminal, the second terminal, and the control terminal of the transistor Tpa may respectively be the collector, the emitter, and the base.

Referring to FIG. 8, an amplifier stage circuit 811 in FIG. 8 is a cascode amplifier in the embodiments of the disclosure. The amplifier stage circuit 811 includes an input terminal PAin, transistors Tpa1 and Tpa2, and an output terminal PAout. A control terminal (gate terminal) of the transistor Tpa1 is coupled to the input terminal PAin, a second terminal (source terminal) of the transistor Tpa1 is coupled to a reference voltage terminal GND, and a first terminal (drain terminal) of the transistor Tpa1 is coupled to a second terminal (source terminal) of the transistor Tpa2. A control terminal of the transistor Tpa2 is coupled to an operating voltage terminal VDN, and a first terminal (drain terminal) of the transistor Tpa2 is coupled to the output terminal PAout. In addition, compared to the common source amplifier in FIG. 7, the cascode amplifier in FIG. 8 has better reverse isolation properties, so it is possible to better configure the reverse isolation of each amplifier path to be better than 35 dB (depending on the frequency of operation, etc.).

Referring to FIG. 9, an amplifier stage circuit 911 in FIG. 9 is a cascade amplifier. The amplifier stage circuit 911 includes an input terminal PAin, transistors Tpa1 and Tpa2, and an output terminal PAout. A control terminal (gate terminal) of the transistor Tpa1 is coupled to the input terminal PAin, a second terminal (source terminal) of the transistor Tpa1 is coupled to a reference voltage terminal GND, and a first terminal (drain terminal) of the transistor Tpa1 is coupled to a control terminal (gate terminal) of the transistor Tpa2. A second terminal (source terminal) of the transistor Tpa2 is coupled to the reference voltage terminal GND, and a first terminal (drain terminal) of the transistor Tpa2 is coupled to the output terminal PAout. In addition, compared to the common source amplifier in FIG. 7, the cascade amplifier in FIG. 9 has better reverse isolation properties, so it is possible to better configure the reverse isolation of each amplifier path to be better than about 35 dB (depending on the frequency of operation, etc.).

Referring to FIG. 10, an amplifier stage circuit 1011 in FIG. 10 is a two-stack amplifier in the embodiments of the disclosure. The amplifier stage circuit 1011 in FIG. 10 includes two stacked transistors and is referred to as a two-stack amplifier. The amplifier stage circuit 1011 in FIG. 10 includes an input terminal PAin, a transistor Tpa1 and a transistor Tpa2, a capacitor Cpa1, a resistor bias circuit 1022, and an output terminal PAout. A control terminal (gate terminal) of the transistor Tpa1 is coupled to the input terminal PAin, and a second terminal (source terminal) of the transistor Tpa1 is coupled to a reference voltage terminal GND. A first terminal (drain terminal) of the transistor Tpa1 is coupled to a second terminal (source terminal) of the transistor Tpa2. A first terminal (drain terminal) of the transistor Tpa2 is coupled to the output terminal PAout. A control terminal (gate terminal) of the transistor Tpa2 is coupled to the reference voltage terminal GND via the capacitor Cpa1. The control terminal of the transistor Tpa2 is also coupled to an operating voltage terminal VDN via the resistor bias circuit 1022. The amplifier stage circuit 1011 may optionally include a capacitor Cpa2 and a resistor-capacitor series circuit 1021. The control terminal of the transistor Tpa1 is coupled to the input terminal PAin via the capacitor Cpa2, and the control terminal of the transistor Tpa1 is also coupled to the reference voltage terminal GND via the resistor-capacitor series circuit 1021. In addition, compared to the cascode amplifier in FIG. 8, the two-stack amplifier in FIG. 10 has better reverse isolation properties, so it is possible to better configure the reverse isolation of each amplifier path to be better than about 35 dB.

Referring to FIG. 11, an amplifier stage circuit 1111 in FIG. 11 is another rendering of a cascode amplifier which is a common-source amplifier in cascade with a common-gate amplifier in the embodiments of the disclosure. The amplifier stage circuit 1111 in FIG. 11 includes two transistors and is referred to as a cascode amplifier, which is a common-source amplifier in cascade with a common-gate amplifier. The amplifier stage circuit 1111 in FIG. 11 includes an input terminal PAin, a transistor Tpa1 and a transistor Tpa2, a capacitor Cpa1, a filter circuit FC1, and an output terminal PAout. A control terminal (gate terminal) of the transistor Tpa1 is coupled to the input terminal PAin, and a second terminal (source terminal) of the transistor Tpa1 is coupled to a reference voltage terminal GND. A first terminal (drain terminal) of the transistor Tpa1 is coupled to a second terminal (source terminal) of the transistor Tpa2. A control terminal (gate terminal) of the transistor Tpa2 is coupled to the reference voltage terminal GND via the capacitor Cpa1. The filter circuit FC1 is coupled between the control terminal of the transistor Tpa2 and the second terminal (source terminal) of the transistor Tpa2. A first terminal (drain terminal) of the transistor Tpa2 serves as a signal output terminal (i.e., the output terminal PAout) of the amplifier stage circuit 1111. The filter circuit FC1 may include a resistor, or may include an inductor-capacitor (LC) circuit or a resistor-inductor-capacitor (RLC) circuit. In addition, compared to the two-stack amplifier in FIG. 10, the cascode amplifier in FIG. 11 also has good reverse isolation properties, so it is possible to better configure the reverse isolation of each amplifier path to be better than 35 dB.

Referring to FIG. 12, an amplifier stage circuit 1211 in FIG. 12 is a multi-stacked-transistors amplifier with three stacked transistors in the embodiments of the disclosure. The multi-stacked-transistors amplifier can be a three-stacked-transistors amplifier (corresponding to FIG. 12), a four-stacked-transistors amplifier, etc. That is, the multi-stacked-transistors amplifier can be an N-stacked-transistors amplifier with N stacked transistors, and N>2. The amplifier stage circuit 1211 in FIG. 12 includes three stacked transistors and is also referred to as a three-stack amplifier. The amplifier stage circuit 1211 in FIG. 12 has a circuit structure that is mainly based on the amplifier stage circuit 1111 in FIG. 11 and further includes an additional stack of transistor, i.e., a transistor Tpa3. The amplifier stage circuit 1211 includes three transistors Tpa1, Tpa2 and Tpa3. Specifically, compared to the amplifier stage circuit 1111 in FIG. 11, the amplifier stage circuit 1211 in FIG. 12 further includes a transistor Tpa3, a capacitor Cpa2, and a filter circuit FC2. A second terminal (source terminal) of the transistor Tpa3 is coupled to the first terminal (drain terminal) of the transistor Tpa2. A control terminal (gate terminal) of the transistor Tpa3 is coupled to the reference voltage terminal GND via the capacitor Cpa2. The filter circuit FC2 is coupled between the control terminal of the transistor Tpa3 and the second terminal (source terminal) of the transistor Tpa3. A first terminal (drain terminal) of the transistor Tpa3 serves as a signal output terminal (i.e., the output terminal PAout) of the amplifier stage circuit 1211. In addition, compared to the cascode amplifier of in FIG. 11, the multi-stacked-transistors amplifier in FIG. 12 has better reverse isolation properties, so it is possible to better configure the reverse isolation of each amplifier path to be significantly better than about 35 dB with just one three-stack amplifier.

A person implementing this embodiment may selectively apply the amplifier stage circuits in FIG. 7 to FIG. 12 to each amplifier stage circuit in the radio frequency power amplifiers in FIG. 1 to FIG. 6. Moreover, when the types of the amplifier stage circuits of the same order in each amplifier path are the same as each other, this embodiment is designed such that the amplifier stage circuits of the same order in each amplifier path can have transistor sizes different from each other.

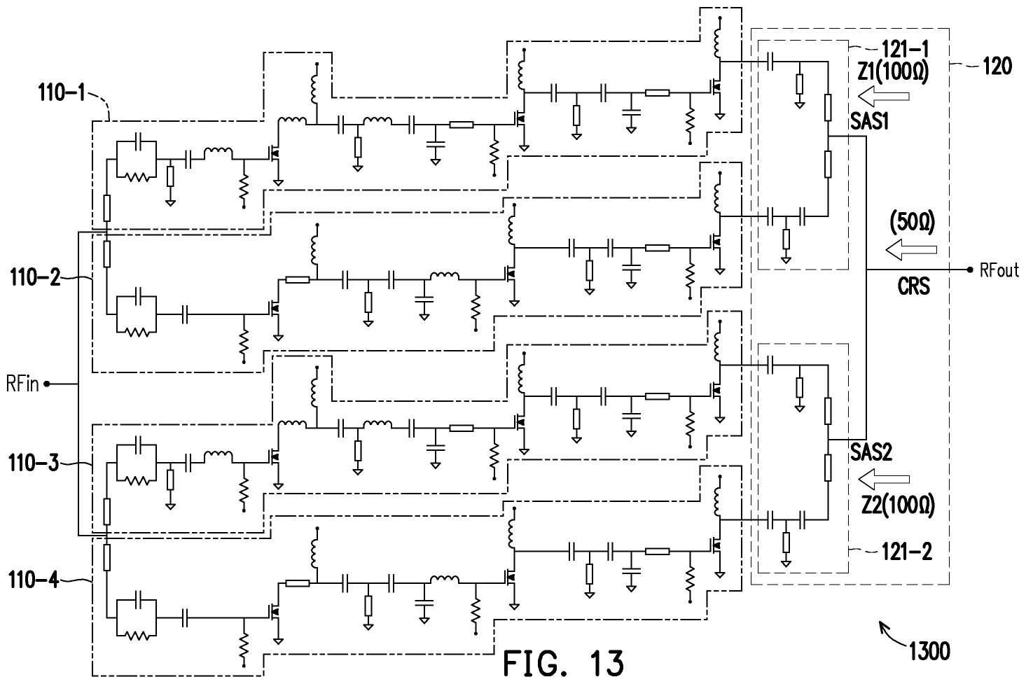

FIG. 13 illustrates a schematic circuit diagram of a radio frequency power amplifier 1300 according to a seventh embodiment of the disclosure. A radio frequency power amplifier in line with the embodiments of the disclosure may include two or more amplifier paths and combine amplified radio frequency signals by the asymmetric power combination circuit 120. For example, the radio frequency power amplifier 1300 in FIG. 13 includes four amplifier paths 110-1 to 110-4 and an asymmetric power combination circuit 120. The circuit structures/parameters of the amplifier paths 110-1 to 110-4 are not exactly the same as each other and form an asymmetric circuit structure. The asymmetric power combination circuit 120 includes power combination sub-circuits 121-1 and 121-2. The power combination sub-circuit 121-1 is configured to combine two amplified radio frequency signals generated by the amplifier paths 110-1 and 110-2 to generate a first combined radio frequency signal SAS1. The power combination sub-circuit 121-2 is configured to combine two amplified radio frequency signals generated by the amplifier path 110-3 and the amplifier path 110-4 to generate a second combined radio frequency signal SAS2. The first and second combined radio frequency signals are superposed to form a combined radio frequency signal CRS to be outputted via the output terminal RFout to provide a higher output power. Moreover, in this embodiment, impedances of the amplifier paths 110-1 to 110-4 and the power combination sub-circuits 121-1 and 121-2 are designed to satisfy the requirements of this embodiment for output impedance. For example, the radio frequency power amplifier 1300 may further include a load circuit 130 coupled to the output terminal RFout as shown in FIG. 2 to FIG. 6. Taking the output terminal RFout as a reference, impedances Z1 and Z2 of the power combination sub-circuits 121-1 and 121-2 are respectively about 100 ohms. Thus, an impedance of the impedances Z1 and Z2 of the power combination sub-circuits 121-1 and 121-2 after being cascaded is substantially equal to the impedance (50 ohms) of the load circuit 130.

In some embodiments, the two-stack amplifier in FIG. 10, the cascode amplifier in FIG. 11, and the multi-stacked-transistors amplifier in FIG. 12 may already have sufficient reverse isolation properties. Thus, with an appropriate design, when the amplifier stage circuit 1011, 1111, or 1211 serves as the last-order amplifier stage circuit among the plurality of cascaded amplifier stage circuits in the amplifier path, or even as a single one-order amplifier stage circuit in the amplifier path, it is already possible to configure the reverse isolation of each amplifier path to be better than about 35 dB. In that case, it is not required to dispose three or more cascaded amplifier stage circuits in each amplifier path.

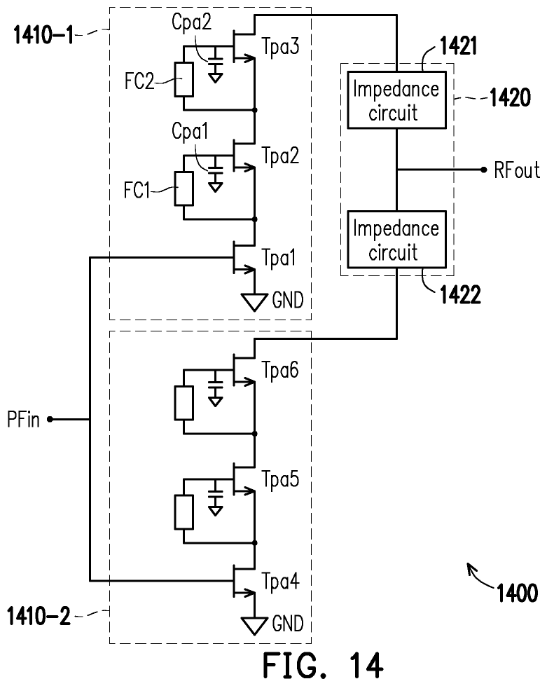

FIG. 14 illustrates a schematic circuit diagram of a radio frequency power amplifier 1400 according to an eighth embodiment of the disclosure. The radio frequency power amplifier 1400 is a detailed circuit configuration in line with the radio frequency power amplifiers 100-1 and 100-2 in FIG. 1 and FIG. 2. The radio frequency power amplifier 1400 mainly includes an input terminal RFin, amplifier paths 1410-1 and 1410-2, an asymmetric power combination circuit 1420, and an output terminal RFout. The amplifier paths 1410-1 and 1410-2 in FIG. 14 each include a one-order amplifier stage circuit, and the circuit structure of this amplifier stage circuit is the same as the amplifier stage circuit 1211 (the three-stack amplifier) in FIG. 12. In addition, the circuit structures/parameters of the amplifier paths 1410-1 and 1410-2 are not the same as each other. The size of a transistor Tpa1 of the amplifier stage circuit in the amplifier path 1410-1 is different from the size of a transistor Tpa4 of the amplifier stage circuit in the amplifier path 1410-2. The size of a transistor Tpa2 of the amplifier stage circuit in the amplifier path 1410-1 is different from the size of a transistor Tpa5 of the amplifier stage circuit in the amplifier path 1410-2. The size of a transistor Tpa3 of the amplifier stage circuit in the amplifier path 1410-1 is different from the size of a transistor Tpa6 of the amplifier stage circuit in the amplifier path 1410-2. The asymmetric power combination circuit 1420 includes impedance circuits 1421 and 1422. Reference may be made to corresponding descriptions of FIG. 1, FIG. 2, FIG. 12, and the embodiments above for the detailed circuit structure and operation of the radio frequency power amplifier 1400 in FIG. 14.

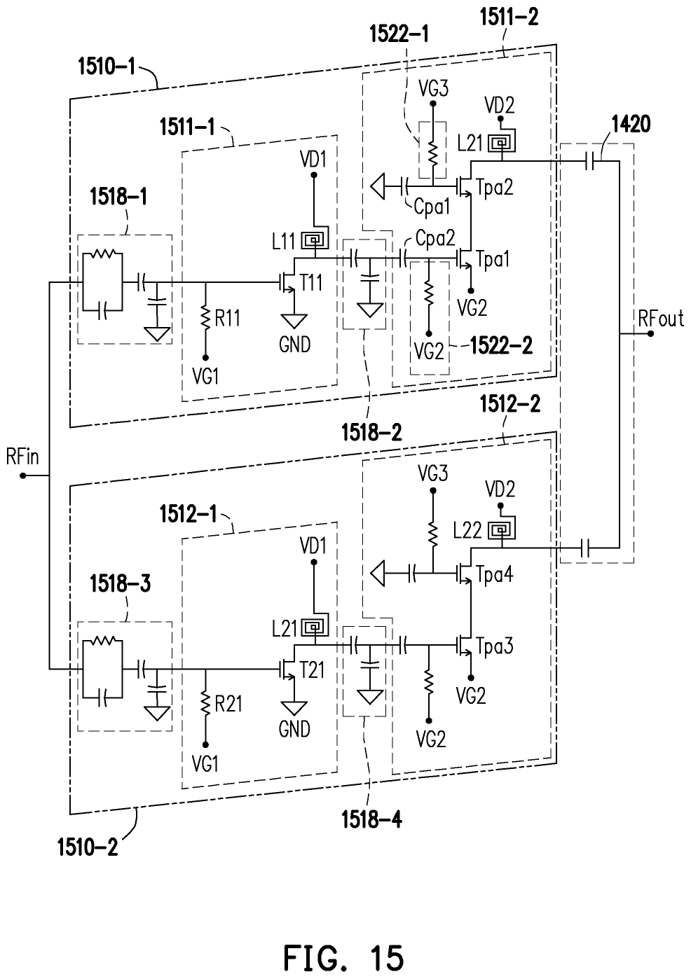

FIG. 15 illustrates a schematic circuit diagram of a radio frequency power amplifier 1500 according to a ninth embodiment of the disclosure. The radio frequency power amplifier 1500 is a detailed circuit configuration in line with the radio frequency power amplifiers 100-1 and 100-2 in FIG. 1 and FIG. 2. The radio frequency power amplifier 1500 includes an input terminal RFin, amplifier paths 1510-1 and 1510-2, an asymmetric power combination circuit 1520, and an output terminal RFout. The amplifier paths 1510-1 and 1510-2 each include two-order amplifier stage circuits 1511-1 to 1511-2 and 1512-1 to 1512-2. The amplifier paths 1510-1 and 1510-2 further include matching circuits 1518-1 to 1518-4. The matching circuit 1518-1 is coupled between the input terminal RFin and the amplifier stage circuit 1511-1 in the amplifier path 1510-1. The matching circuit 1518-2 is coupled between the amplifier stage circuits 1511-1 and 1511-2. The matching circuit 1518-3 is coupled between the input terminal RFin and the amplifier stage circuit 1512-1 in the amplifier path 1510-2. The matching circuit 1518-4 is coupled between the amplifier stage circuits 1512-1 and 1512-2.

The first-order amplifier stage circuits 1511-1 and 1512-1 in the amplifier paths 1510-1 and 1510-2 are both common source amplifiers (similar to the circuit structure of the common source amplifier 711 in FIG. 7), but the circuit structures/parameters (especially the size of the transistor) of the two are slightly different. The first-order amplifier stage circuits 1511-1 and 1512-1 in the amplifier paths 1510-1 and 1510-2 are both common source amplifiers. The amplifier stage circuit 1511-1 includes a transistor T11 that constitutes the common source amplifier. The amplifier stage circuit 1511-1 may further optionally include a resistor R11, an inductor L11, and other circuit elements not shown on FIG. 15. The inductor L11 is coupled to an operating voltage terminal VD1. The resistor R11 is coupled to an operating voltage terminal VG1. The amplifier stage circuit 1512-1 includes a transistor T21 that constitutes the common source amplifier. The amplifier stage circuit 1512-1 may further optionally include a resistor R21, an inductor L21, and other circuit elements not shown on FIG. 15. The inductor L21 is coupled to the operating voltage terminal VD1. The resistor R21 is coupled to the operating voltage terminal VG1.

The second-order amplifier stage circuits 1511-2 and 1512-2 in the amplifier paths 1510-1 and 1510-2 are both two-stack amplifiers (similar to the circuit structure of the two-stack amplifier 1011 in FIG. 10), but the circuit structures/parameters (especially the size of the transistor) of the two are slightly different. Taking the amplifier stage circuit 1511-2 as an example, the amplifier stage circuit 1511-2 mainly includes cascaded transistors Tpa1 and Tpa2, a capacitor Cpa1, and a resistor bias circuit 1522-1. The amplifier stage circuit 1511-2 may further optionally include a capacitor Cpa2 and a resistor bias circuit 1522-2. A control terminal of the transistor Tpa1 is coupled to an input terminal PAin via the capacitor Cpa2. The control terminal of the transistor Tpa1 is also coupled to the operating voltage terminal VG1 via the resistor bias circuit 1522-2. A control terminal of the transistor Tpa2 is coupled to a reference voltage terminal GND via the capacitor Cpa1. The control terminal of the transistor Tpa2 is also coupled to an operating voltage terminal VG3 via the resistor bias circuit 1522-1. The circuit structure of the amplifier stage circuit 1511-2 is similar to that of the amplifier stage circuit 1512-2, but the size of the transistor Tpa1 is different from that of the transistor Tpa3, and the size of the transistor Tpa2 is different from that of the transistor Tpa4.

Table 4 shows some simulated properties of the radio frequency power amplifier 1500. Table 5 shows some simulated properties when the two-stack amplifiers of the second-order amplifier stage circuits 1511-2 and 1512-2 of the radio frequency power amplifier 1500 are both replaced with common source stage amplifiers. That is, in the radio frequency power amplifier corresponding to Table 4, the first-order amplifier stage circuits and the second-order amplifier stage circuits are all common source amplifiers. As can be learned from Table 4 and Table 5, although the radio frequency power amplifier 1500 only includes two orders of amplifier stage circuits, since the last order is the two-stack amplifiers, it is possible to provide sufficient isolation and provide better small signal gain, 1 dB compression point (OP1 dB), power-added efficiency at output power 1 dB compression point (PAE@P1 dB), and maximum power-added efficiency (Max. PAE) at multiple frequencies, which thus better satisfy the requirements for broadband operation.

TABLE 4

| | | | |
|---|---|---|---|
| Frequency (GHz) | 24 | 28 | 30 |
| Gain (dB) | 17.8 | 20.6 | 20.4 |
| OP1dB (dBm) | 26.4 | 27.3 | 26.6 |
| Max. PAE (%) | 28.5 | 36.2 | 30.5 |
| Pout, SAT (dBm) | 34 | 42.4 | 44 |

TABLE 5

| | | | |
|---|---|---|---|
| Frequency (GHz) | 24 | 28 | 30 |
| Gain (dB) | 14.5 | 15.8 | 14.4 |
| OP1dB (dBm) | 18.7 | 26 | 26.3 |
| Max. PAE (%) | 24.4 | 25 | 27.3 |
| Pout, SAT (dBm) | 22.7 | 32.3 | 29.8 |

In summary of the above, the radio frequency power amplifier provided in the embodiments of the disclosure is implemented by connecting at least two different amplifier paths in parallel with each other. These amplifier paths include the same number of multiple cascaded amplifier stage circuits, but the amplifier stage circuits of the same order in these amplifier paths do not have the same circuit structure/parameters, but respectively have circuit structures/parameters different from each other (e.g., different transistor sizes, bias voltages, phases, signal gains, etc.) and form an asymmetric circuit structure. In the embodiments of the disclosure, at least two different amplifier paths forming an asymmetric circuit structure are used as an asymmetric power combination, and the corresponding output impedances of these two different amplifier paths are designed to be substantially complex conjugate matched (if more than two paths the combined output impedance just need to be matched closely to the load for effective asymmetric power combining), and the reverse isolation of each amplifier path is better than a specific minimum value (e.g., 35 dB, depending on the frequency of operation). Accordingly, the radio frequency power amplifier can have a sufficiently wide transmission bandwidth and a sufficient peak power-added efficiency. Thus, it is possible to provide sufficient transmission rate, signal gain, and lower power consumption. On the other hand, the control circuit May correspondingly adjust the adjustable circuit elements in the impedance circuit based on the electrical property (e.g., signal frequency, signal power, etc.) of the radio frequency signal or the amplified radio frequency signal detected by the detection circuit to thus dynamically adjust the output impedance of the radio frequency power amplifier and further improve the performance of the radio frequency power amplifier.

What is claimed is:

1. A radio frequency power amplifier comprising:
an input terminal receiving a radio frequency signal;
at least two amplifier paths, each of the amplifier paths being coupled to the input terminal, and each of the amplifier paths amplifying the radio frequency signal to generate a corresponding amplified radio frequency signal;
an asymmetric power combination circuit coupled to the amplifier paths and combining the amplified radio frequency signals generated by the amplifier paths to generate a combined radio frequency signal; and
an output terminal outputting the combined radio frequency signal, wherein
each of the amplifier paths generates the corresponding amplified radio frequency signal simultaneously, and a reverse isolation of each of the amplifier paths is better than 35 dB.

2. The radio frequency power amplifier according to claim 1, wherein each of the amplifier paths comprises a plurality of cascaded amplifier stage circuits.

3. The radio frequency power amplifier according to claim 2, wherein a number of the cascaded amplifier stage circuits in each of the amplifier paths is greater than or equal to three.

4. The radio frequency power amplifier according to claim 2, wherein a last-order amplifier stage circuit among the amplifier stage circuits in each of the amplifier paths is a common source amplifier, a common emitter amplifier, a cascode amplifier, a two-stack amplifier, a cascode amplifier having a common-source amplifier in cascade with a common-gate amplifier, or a multi-stacked-transistors amplifier.

5. The radio frequency power amplifier according to claim 2, wherein the cascaded amplifier stage circuits in each of the amplifier paths are all common source amplifiers or common emitter amplifiers, or a combination of a common source amplifier, a common emitter amplifier, a cascode amplifier, and a multi-stacked-transistors amplifier.

6. The radio frequency power amplifier according to claim 2, wherein the amplifier stage circuits of a same order in each of the amplifier paths have transistor sizes different from each other.

7. The radio frequency power amplifier according to claim 2, wherein a last-order amplifier stage circuit among the amplifier stage circuit in each of the amplifier paths comprises:
a first transistor and a second transistor cascaded with each other;
a first capacitor, wherein a control terminal of the second transistor is coupled to a reference voltage terminal via the first capacitor; and
a first resistor bias circuit, wherein the control terminal of the second transistor is coupled to an operating voltage terminal via the first resistor bias circuit.

8. The radio frequency power amplifier according to claim 2, wherein a last-order amplifier stage circuit among the amplifier stage circuit in each of the amplifier paths comprises:
a first transistor and a second transistor cascaded with each other;
a first capacitor, wherein a control terminal of the second transistor is coupled to a reference voltage terminal via the first capacitor; and
a first filter circuit coupled between the control terminal of the second transistor and a second terminal of the second transistor, wherein a first terminal of the second transistor serves as a signal output terminal of the amplifier stage circuit, and the second terminal of the second transistor is coupled to a first terminal of the first transistor.

9. The radio frequency power amplifier according to claim 2, wherein the cascaded amplifier stage circuits in each of the amplifier paths receive operating voltages, and the operating voltage of a last-order amplifier stage circuit among the amplifier stage circuits in each of the amplifier paths is greater than the operating voltages of other-order amplifier stage circuits among the amplifier stage circuits.

10. The radio frequency power amplifier according to claim 2, wherein one of the amplifier stage circuits comprises a cascade amplifier, and the cascade amplifier comprises a first transistor and a second transistor cascaded with each other, the one of the amplifier stage circuits further comprising:
a first capacitor, wherein a control terminal of the second transistor is coupled to a reference voltage terminal via the first capacitor; and
a first resistor bias circuit, where the control terminal of the second transistor is coupled to an operating voltage terminal via the first resistor bias circuit.

11. The radio frequency power amplifier according to claim 2, wherein one of the amplifier stage circuits comprises a cascade amplifier, and the cascade amplifier comprises a first transistor and a second transistor cascaded with each other, the one of the amplifier stage circuits further comprising:
a first capacitor, wherein a control terminal of the second transistor is coupled to a reference voltage terminal via the first capacitor; and
a first filter circuit coupled between the control terminal of the second transistor and a second terminal of the second transistor, wherein a first terminal of the second transistor serves as a signal output terminal of the amplifier stage circuit, and the second terminal of the second transistor is coupled to a first terminal of the first transistor.

12. The radio frequency power amplifier according to claim 1, wherein each of the amplifier paths comprises at least one amplifier stage circuit, and the at least one amplifier stage circuit is coupled to the asymmetric power combination circuit, the at least one amplifier stage circuit comprising:
a first transistor and a second transistor cascaded with each other; and
a first resistor bias circuit, wherein a control terminal of the second transistor is coupled to an operating voltage terminal via the first resistor bias circuit.

13. The radio frequency power amplifier according to claim 1, wherein each of the amplifier paths comprises at least one amplifier stage circuit, and the at least one amplifier stage circuit is coupled to the asymmetric power combination circuit, the at least one amplifier stage circuit comprising:
a first transistor and a second transistor cascaded with each other; and
a first filter circuit coupled between a control terminal of the second transistor and a second terminal of the second transistor, wherein a first terminal of the second transistor serves as a signal output terminal of the amplifier stage circuit, and the second terminal of the second transistor is coupled to a first terminal of the first transistor.

14. The radio frequency power amplifier according to claim 1, wherein the at least two amplifier paths comprise a first amplifier path and a second amplifier path, and the asymmetric power combination circuit comprises:
a first impedance circuit coupled between the output terminal and the first amplifier path, wherein, taking the output terminal as a reference, the first impedance circuit has a first impedance; and
a second impedance circuit coupled between the output terminal and the second amplifier path, wherein, taking the output terminal as a reference, the second impedance circuit has a second impedance, wherein
the first impedance and the second impedance are substantially complex conjugate matched.

15. The radio frequency power amplifier according to claim 14, further comprising:
a load circuit coupled to the output terminal, wherein
an equivalent impedance formed by the first impedance and the second impedance is equal to an impedance of the load circuit.

16. The radio frequency power amplifier according to claim 14, wherein the first impedance corresponding to the first impedance circuit and the second impedance corresponding to the second impedance circuit are variable, and the radio frequency power amplifier further comprises:
a detection circuit detecting an electrical property of the radio frequency signal or the combined radio frequency signal and generating a detection signal; and
a control circuit coupled to the detection circuit and controlling at least a part of circuit elements in the first impedance circuit and the second impedance circuit according to the detection signal to adjust the first impedance and the second impedance.

17. The radio frequency power amplifier according to claim 1, wherein the at least two amplifier paths comprise a first amplifier path, a second amplifier path, a third amplifier path, and a fourth amplifier path, and
the asymmetric power combination circuit comprises a first power combination sub-circuit and a second power combination sub-circuit, wherein the first power combination sub-circuit combines two first amplified radio frequency signals generated by the first amplifier path and the second amplifier path to generate a first combined radio frequency signal, the second power combination sub-circuit combines two second amplified radio frequency signals generated by the third amplifier path and the fourth amplifier path to generate a second combined radio frequency signal, wherein
the first combined radio frequency signal and the second combined radio frequency signal are superposed to form the combined radio frequency signal.

18. The radio frequency power amplifier according to claim 1, wherein the reverse isolation is an amplifier reverse transmission response measured from an output terminal of the amplifier path to an input terminal of the amplifier path.

19. A radio frequency power amplifier comprising:
an input terminal receiving a radio frequency signal;
at least two amplifier paths, each of the amplifier paths being coupled to the input terminal, and each of the amplifier paths amplifying the radio frequency signal to generate a corresponding amplified radio frequency signal; and
an asymmetric power combination circuit coupled to the amplifier paths and combining the amplified radio frequency signals generated by the amplifier paths to generate a combined radio frequency signal, wherein
each of the amplifier paths generates the corresponding amplified radio frequency signal simultaneously, and each of the amplifier paths comprises:
a first transistor, a second transistor and a third transistor cascoded with each other;
a first capacitor, wherein a control terminal of the second transistor is coupled to a reference voltage terminal via the first capacitor;
a first filter circuit coupled between the control terminal of the second transistor and a second terminal of the second transistor, and the second terminal of the second transistor is coupled to a first terminal of the first transistor;
a second capacitor, wherein a control terminal of the third transistor is coupled to the reference voltage terminal via the second capacitor; and
a second filter circuit coupled between the control terminal of the third transistor and a second terminal of the third transistor, wherein a first terminal of the third transistor serves as a signal output terminal of the amplifier path, and the second terminal of the third transistor is coupled to a first terminal of the second transistor.

20. The radio frequency power amplifier according to claim 19, wherein a reverse isolation of each of the amplifier paths is better than 35 dB.
